(19) United States
(12) Patent Application Publication
(10) Pub. No.: US 2026/0114273 A1
(43) Pub. Date: Apr. 23, 2026

(54) SEMICONDUCTOR APPARATUS

(71) Applicant: Mitsubishi Electric Corporation, Tokyo (JP)

(72) Inventor: Tatsuki ONOMATA, Tokyo (JP)

(73) Assignee: Mitsubishi Electric Corporation, Tokyo (JP)

(21) Appl. No.: 19/221,420

(22) Filed: May 28, 2025

(30) Foreign Application Priority Data
Oct. 23, 2024 (JP) 2024-186688

(51) Int. Cl. H01L 23/367; H01L 23/00; H01L 23/047; H01L 23/373

(52) U.S. Cl. CPC H10W 40/226; H10W 40/255; H10W 76/134; H10W 72/884; H10W 90/734; H10W 90/754

(57) ABSTRACT

A semiconductor apparatus according to this disclosure includes an insulating substrate; a semiconductor device bonded to one side surface of the insulating substrate; a base plate with one side surface bonded to the other side surface of the insulating substrate and having a warped shape on the other side surface; and a heat dissipation sheet in contact with the other side surface of the base plate, wherein the heat dissipation sheet is solid, and one side surface of the heat dissipation sheet has a shape conforming to the warped shape of the base plate.

### BACKGROUND

### Field

The present disclosure relates to a semiconductor apparatus.

### BACKGROUND

For example, JP 2018-133527 A describes a device characterized by comprising a bonding layer containing a thermocompression bonding type adhesive at least one of the spaces between a semiconductor module and a heat dissipation sheet, and between the heat dissipation sheet and the cooling device provided on the side opposite to the semiconductor module.

The aforementioned prior art has a problem where the heat dissipation sheet may not sufficiently conform to the warpage of the base plate of a rear surface of the semiconductor module. Due to the insufficient contact area between the heat dissipation sheet and the base plate relative to the surface area of the base plate, there was a skewing of the heat dissipation path, preventing adequate heat transfer to the fins.

### SUMMARY

Therefore, the present disclosure aims to provide a heat dissipation sheet that can improve heat dissipation efficiency by increasing the contact area between a base plate with a warpage and a heat dissipation sheet.

The features and advantages of the present disclosure may be summarized as follows.

According to an aspect of the present disclosure, a semiconductor apparatus includes an insulating substrate; a semiconductor device bonded to one side surface of the insulating substrate; a base plate with one side surface bonded to the other side surface of the insulating substrate and having a warped shape on the other side surface; and a heat dissipation sheet in contact with the other side surface of the base plate, wherein the heat dissipation sheet is solid, and one side surface of the heat dissipation sheet has a shape conforming to the warped shape of the base plate.

Other and further objects, features and advantages of the disclosure will appear more fully from the following description.

### BRIEF DESCRIPTION OF DRAWINGS

FIG. 1 and FIG. 2 are cross-sectional views of a semiconductor apparatus according to Embodiment 1.

FIG. 3 is a bottom view of the heat dissipation sheet in the semiconductor apparatus according to a modification of Embodiment 1.

FIG. 4 is a cross-sectional view of the semiconductor apparatus according to Embodiment 2.

FIG. 5 is a bottom view of the heat dissipation sheet in the semiconductor apparatus according to Embodiment 2.

### DESCRIPTION OF EMBODIMENTS

### 1. Embodiment 1

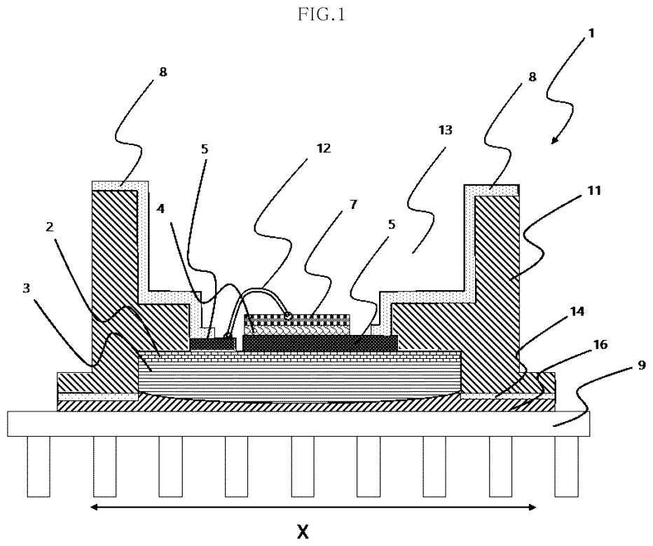

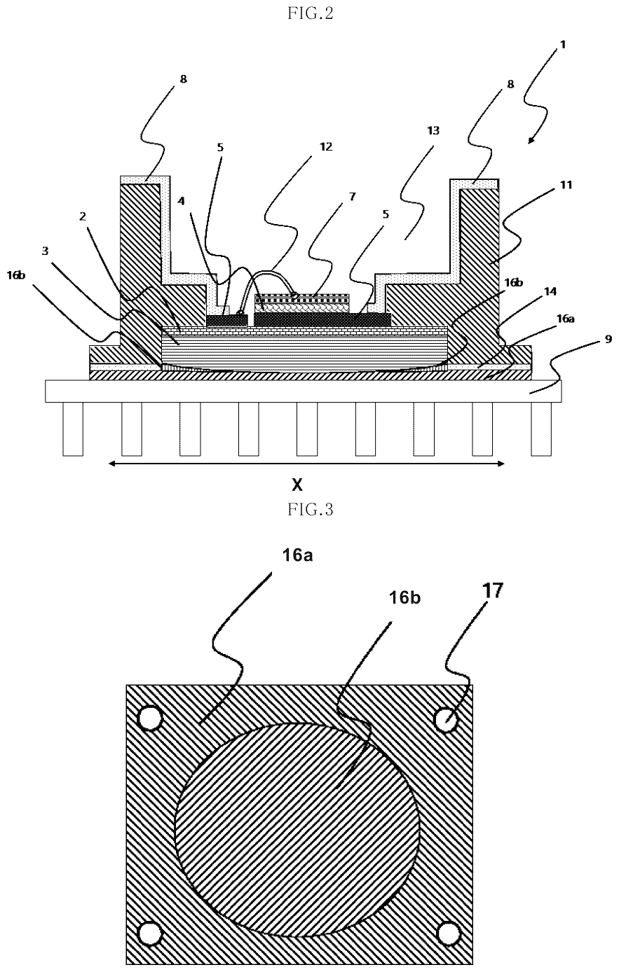

The semiconductor apparatus 1 according to Embodiment 1 will be described with reference to the drawings. FIG. 1 is a cross-sectional view of the semiconductor apparatus 1 according to Embodiment 1. FIG. 2 is a cross-sectional view of the semiconductor apparatus 1 according to Embodiment 1. FIG. 3 is a bottom view of the heat dissipation sheet 16 in the semiconductor apparatus 1 according to a modification of Embodiment 1.

### 1-1.Configuration of the Semiconductor Apparatus 1

The semiconductor apparatus 1 includes an insulating substrate 2, a semiconductor device 7 bonded to one side surface of the insulating substrate 2, a base plate 3 with one side surface bonded to the other side surface of the insulating substrate 2 and a warp on the other side surface, and a heat dissipation sheet 16 in contact with the other side surface of the base plate 3. The heat dissipation sheet 16 is solid and has one side surface shaped to conform to the warped shape of the base plate 3.

In the present disclosure, a direction perpendicular to the direction in which the base plate 3 and the heat dissipation sheet 16 are joined is defined as a first direction.

### Insulating Substrate 2

The insulating substrate 2 in this embodiment has the semiconductor device 7 joined to one side surface and the base plate 3 joined to the other side surface, with the material composed of ceramic, resin, etc. A bonding material 4 such as solder is used to join the insulating substrate 2, the base plate 3, and the semiconductor device 7. On top of the insulating substrate 2, a circuit pattern is formed. For example, the circuit pattern is formed by etching copper or the like.

For instance, the insulating substrate is composed of a circuit board and an insulating board. The insulating substrate is laminated in the order of circuit board, insulating board, and circuit board, with the insulating board sandwiched between the two circuit boards. The circuit board is mainly made of copper, constituting the circuit pattern. The insulating board is formed from ceramic materials with insulating properties, such as alumina. By inserting an insulator between two types of circuit boards, each of the electrical circuits formed by the two types of circuit boards does not interfere, preventing shorts and electrical problems.

An bonding material is provided on both sides of the insulating substrate (one side surface of the circuit board on the one side and the other side surface of the circuit board on the other side). The main bonding material used is solder, but a sintering material using metal paste such as silver paste may also be used. A semiconductor device or a capacitor chip is attached to one side surface of the insulated substrate where the bonding material is provided, and a heat sink is attached to the other side surface of the insulated substrate where the bonding material is provided.

Multiple insulated substrates are connected to each other via bonding wires. On one side surface of each insulating substrate, the end of a bonding wire is attached so as to be connected to the circuit board.

### Semiconductor Device 7

The semiconductor device 7 of this embodiment is bonded to one side surface of the circuit pattern formed on the insulating substrate 2. The semiconductor device 7 may be an IGBT (Insulated Gate Bipolar Transistor) or a diode. The semiconductor device 7 is connected to the electrode terminal mounted on the case using a wire. For the wire, materials such as copper or aluminum are used.

For example, the semiconductor device is bonded to one side surface of an insulating substrate. The other side surface of the semiconductor device is attached to the one side surface of the insulating substrate through the bonding material.

On one side surface of the semiconductor device, one end of the bonding wire is joined. The other end of the bonding wire is connected to the external terminal. The semiconductor apparatus is electrically connected to the outside through the bonding wire.

In the semiconductor device of this example, an IGBT is used. The IGBT is used for high-voltage, high-current switching, and is utilized in motor controls and inverter circuits. The types of semiconductor devices are not limited to IGBT; MOSFET and other types are also acceptable.

### Base Plate 3

The base plate 3 in this embodiment has one side surface bonded to the other side surface of the insulating substrate 2. The base plate 3 has warping on the other side surface. Copper or aluminum is mainly used for the base plate 3. In this embodiment, the warping is convex, with the protrusion height increasing as it approaches the center. The other side surface of the base plate 3 has a convex spherical warp. Additionally, the warp may be a convex warp that increases in protrusion height as it approaches the central part of a specific first direction, as in Embodiment 2. In this case, the other side surface of the base plate 3 has a cylindrical spherical warp.

### Other Configurations of the Semiconductor Apparatus 1

The semiconductor apparatus 1 of this embodiment is enclosed by a resin case 11. The resin case 11 has a roughly rectangular box shape. It has a structure that allows the insulating substrate 2 and semiconductor device 7 to be housed inside, and even if the liquid sealing material 13 or the like is poured into the resin case 11, it does not leak outside. The material of the resin case 11 is formed from resin such as PPS (polyphenylene sulfide). Other resins may be used in place of PPS (polyphenylene sulfide).

As mentioned above, one end of the bonding wire 12 is attached to a part of one side surface of the semiconductor device 7. The other end of the bonding wire 12 is connected to one end of the circuit board 5. The circuit board 5 is in contact with the external terminal 8, which extends along the inner surface of the resin case 11, and the other end of the external terminal 8 is exposed to the outside from the resin case 11 and the sealing material 13. The external terminal 8, which is exposed to the outside, can connect to external components by making contact with other parts.

The semiconductor device 7, the insulation substrate 2, and the bonding wire 12 are enclosed by the resin case 11 and the base plate 3. The sealing material 13 is filled inside the resin case 11 and the heat dissipation plate, which protects components such as the semiconductor device 7 and the insulation substrate 2.

### Heat Dissipating Sheet 16

The heat dissipating sheet 16 of this embodiment is in contact with the other side surface of the base plate 3. The heat dissipating sheet 16 is solid, and one side surface of the heat dissipating sheet 16 has a shape that follows the warped shape of the base plate 3. With this configuration, the heat dissipating sheet 16 can sufficiently contact the surface area of the other side surface of the base plate 3. By sufficiently contacting, it becomes possible to efficiently dissipate the heat from the base plate 3 through the heat dissipating sheet 16. The heat dissipated is transferred to the fins, which are the cooler 9, joined to the other side surface of the heat dissipation sheet 16, cooling the semiconductor apparatus 1. In the disassembled state of the heat dissipation sheet 16 and the base plate 3, the shape of one side surface of the heat dissipation sheet 16 is maintained according to the warped shape of the base plate 3.

In this embodiment, a portion of one side surface of the heat dissipation sheet 16 that is in contact with the base plate 3 does not have adhesive properties. By configuring the adhesive parts to be on the resin case 11 rather than on the base plate 3 that is exposed on the other side surface of the semiconductor apparatus 1, it is possible to reduce the effect of heat dissipation.

In this embodiment, a portion of one side surface of the heat dissipation sheet 16 that does not contact the base plate 3 has adhesive properties and is bonded to the base plate 3 side (in this example, the resin case 11). Because, in the semiconductor apparatus 1, the area directly below the semiconductor device 7 has the highest heat, efficiently dissipating the heat directly below the semiconductor device 7 becomes vital for cooling semiconductor apparatus 1. Therefore, in this embodiment, the bonding part with lower thermal conductivity compared to heat dissipating sheet 16 is arranged to avoid the base plate 3 located directly below the semiconductor device 7. This configuration allows for an increase in heat dissipation efficiency.

In this embodiment, the heat dissipation sheet 16 has a mounting hole 17 in the part that does not come into contact with the base plate 3, and it is fixed to the base plate 3 side (in this example, the resin case 11) using the mounting hole 17. For instance, a fastening member such as a screw or bolt is inserted through the mounting hole 17, thus securing the heat dissipation sheet 16 to the resin case 11. This configuration makes it possible to attach the semiconductor apparatus 1 to the cooler 9 while the heat dissipation sheet 16 is in an adhered state. As a result, it is possible to omit the positioning of the semiconductor apparatus 1 and the heat dissipation sheet 16.

In this embodiment, the heat dissipation sheet 16 contains graphite as a component. Graphite has high thermal conductivity and is widely used as a material for the heat dissipation sheet 16. Furthermore, the heat dissipation sheet 16 is formed with a hardness in the range of 30 to 70 degrees of Type E hardness. This configuration makes it possible to increase heat dissipation efficiency. Additionally, graphite has thermal conductivity anisotropy, and the graphite layers are provided vertically with respect to the base plate 3. This configuration allows for higher thermal conductivity of the graphite. Graphite may not necessarily have thermal conductivity anisotropy.

In this embodiment, the thickness of the heat dissipation sheet 16 varies according to the warp of the base plate 3. As the protrusion height on the other side surface of the base plate 3 increases, the thickness of the heat dissipation sheet 16 is reduced. This configuration makes it possible to conform the one side surface of the heat dissipation sheet 16 to the warp, while keeping the other side surface of the heat dissipation sheet 16 flat, and when attaching the fins, which are the coolers 9, to the other side surface of the heat dissipation sheet 16, it becomes possible to bond the other side surface of the heat dissipation sheet 16.

In a modification example of the present embodiment, the heat dissipation sheet 16 consists of two sheets with different thicknesses. As shown in FIG. 2, the second heat dissipation sheet 16b on the base plate 3 side and the first heat dissipation sheet 16a on the side opposite to the base plate 3 are overlapped. One side surface of the second heat dissipation sheet 16b has a shape conforming to the warped shape of the base plate 3, and the other side surface of the second heat dissipation sheet 16b is flat and adheres to one side surface of the first heat dissipation sheet 16a. The first heat dissipation sheet 16a is formed in a flat plate shape and is larger than the second heat dissipation sheet 16b. Since the heat dissipation sheet 16 is mainly composed of graphite, polishing is difficult, and it is challenging to create a variation in thickness within a single sheet. This configuration makes it possible to easily process heat dissipation sheets 16 with different thicknesses. Furthermore, as shown in FIG. 3, it is acceptable to compose it with the first heat dissipating sheet 16a that has a central part punched out, and the second heat dissipating sheet 16b that fit with the shape of the hole. The second heat dissipating sheet 16b faces the base plate 3 and has a shape that conforms to the warped shape of the base plate 3.

### 2.Embodiment 2

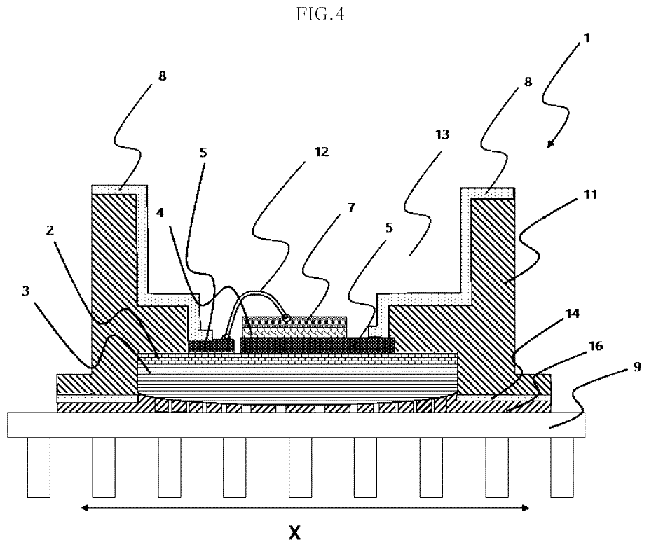

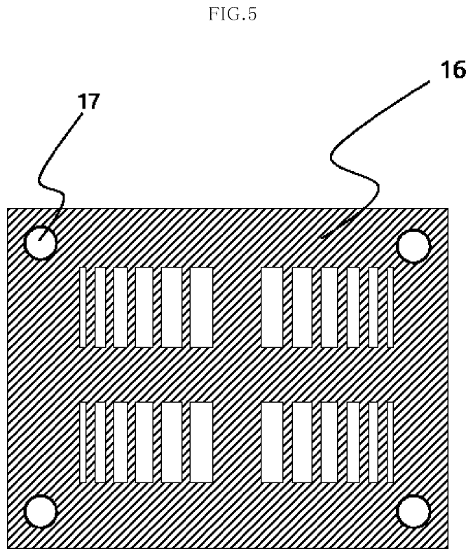

The semiconductor apparatus 1 according to Embodiment 2 will be described with reference to the drawings. FIG. 4 is a cross-sectional view of the semiconductor apparatus 1 according to Embodiment 2. FIG. 5 is a bottom view of the heat dissipation sheet 16 in the semiconductor apparatus 1 according to Embodiment 2.

The heat dissipation sheet 16 according to this embodiment has a plurality of slits. According to this configuration, when the heat-dissipating sheet 16 is pressed against the base plate 3, the width of the slit changes, which makes it easier for the thickness of the portion of the heat-dissipating sheet 16 adjacent to the slit to change, and the heat sheet is more likely to deform along the warp of the base plate 3's convex shape. Moreover, having a large contacting surface makes it possible to increase heat dissipation efficiency. Additionally, the shape of the slit can be curved or polygonal.

The warp of the base plate 3 in this embodiment is a convex warp where the protrusion height increases as it approaches the center. The other side surface of the base plate 3 has a cylindrical spherical warp. According to this configuration, the base plate 3 of the semiconductor apparatus 1 has a convex warp with the highest protrusion height at the center part in the first direction. Note that, similar to Embodiment 1, the other side surface of the base plate 3 may have a convex spherical warp.

In this embodiment, the width of each of the plurality of slits increases as a protruding height of the warped shape facing each of the slits increases. According to this configuration, because the base plate 3 of the semiconductor apparatus 1 has a convex warped shape where the center part has the greatest protrusion height, by widening the slit intervals in the central part of the heat dissipation sheet 16, it is possible to secure space for the heat dissipation sheet 16 to expand into the slits at areas where the protrusion height and pushing force are greater, making it easier to deform along the warp. The slit intervals become narrower toward the edge of the base plate 3. This configuration allows for a reduction in gaps between the heat dissipation sheet 16 and the base plate 3 in areas where the pressing force is small, and the deformation is minimal. Moreover, by reducing the gaps, it is possible to improve the heat dissipation efficiency.

The warpage according to this embodiment is a warpage where the protrusion height differs at each position in the first direction, and the multiple slits are arranged in the first direction. According to this configuration, by aligning the first direction in which the protruding heights are different with the direction in which multiple slits are arranged, it becomes easier to deform the heat dissipation sheet 16 according to the difference in protruding heights at each position in the first direction.

When there is a variation in the protruding heights due to individual differences, the width of the multiple slits in each individual may be varied according to the variation in the protruding heights of each individual. In other words, for each individual product, the width of the slit may be varied according to the protruding height of the warped part facing each slit, so that the width of the slit increases as the protruding height of the warped part facing each slit increases. Even if individual differences occur where the protruding height varies by position, the heat dissipation sheet 16 can be properly deformed to align the heat dissipation sheet 16 with the warping of the base plate 3.

According to the semiconductor apparatus related to this disclosure, it is possible to improve the heat dissipation efficiency by forming a heat dissipation sheet along the warp of the base plate to expand the contact area with the base plate.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-186688, filed on Oct. 23, 2024 including specification, claims, drawings and summary, on which the Convention priority of the present application is based, are incorporated herein by reference in its entirety.

1. A semiconductor apparatus comprising:
an insulating substrate;
a semiconductor device bonded to one side surface of the insulating substrate;
a base plate with one side surface bonded to the other side surface of the insulating substrate and having a warped shape on the other side surface; and
a heat dissipation sheet in contact with the other side surface of the base plate, wherein
the heat dissipation sheet is solid, and
one side surface of the heat dissipation sheet has a shape conforming to the warped shape of the base plate.

2. The semiconductor apparatus according to claim 1, wherein a portion of the one side surface of the heat dissipation sheet that is in contact with the base plate does not have adhesiveness.

3. The semiconductor apparatus according to claim 1, wherein a portion of the one side surface of the heat dissipation sheet that is not in contact with the base plate has adhesiveness, and
the portion is bonded to the base plate side.

4. The semiconductor apparatus according to claim 1, wherein the heat dissipation sheet has a hardness measured by a type E durometer that falls within the range of 30 to 70 degrees.

5. The semiconductor apparatus according to claim 1, wherein the heat dissipation sheet has a mounting hole in a portion not in contact with the base plate, and
the heat dissipation sheet is fixed to the base plate side using the mounting hole.

6. The semiconductor apparatus according to claim 1, wherein the other side surface of the heat dissipation sheet is flat.

7. The semiconductor apparatus according to claim 1, wherein the heat dissipation sheet includes graphite as a component.

8. The semiconductor apparatus according to claim 1, wherein the heat dissipation sheet has a thickness that varies depending on a warp of the base plate.

9. The semiconductor apparatus according to claim 1, wherein the heat dissipation sheet includes two sheets with different thicknesses.

10. The semiconductor apparatus according to claim 1, wherein the heat dissipation sheet has a plurality of slits.

11. The semiconductor apparatus according to claim 1, wherein the warped shape is a convex warp with a protruding height that increases as it approaches the center.

12. The semiconductor apparatus according to claim 10, wherein the warped shape is a warp with different protruding heights at each position in a first direction, and
the plurality of slits are arranged in the first direction.

13. The semiconductor apparatus according to claim 10, wherein the width of each of the plurality of slits increases as a protruding height of the warped shape facing each of the slits increases.
